(19) United States
(12) Patent Application Publication
(10) Pub. No.: US 2025/0233217 A1
(43) Pub. Date: Jul. 17, 2025

(54) BATTERY SYSTEM

(71) Applicant: TOYOTA JIDOSHA KABUSHIKI KAISHA, Toyota-shi (JP)

(72) Inventor: Yoshiki TSUCHIDA, Toyota-shi (JP)

(73) Assignee: TOYOTA JIDOSHA KABUSHIKI KAISHA, Toyota-shi (JP)

(21) Appl. No.: 18/905,666

(22) Filed: Oct. 3, 2024

(30) Foreign Application Priority Data
Jan. 12, 2024 (JP) 2024-002999

(51) Int. Cl. H01M 10/44; G01R 31/3842; G01R 31/392; H01M 10/48

(52) U.S. Cl. CPC H01M 10/443; G01R 31/3842; G01R 31/392; H01M 10/486

(57) ABSTRACT

A battery system including a battery, wherein the battery is connected to a power system, and includes a detection unit that detects an abnormality of the battery system, and a battery control unit that causes the battery to discharge to the power system when the detection unit detects the abnormality.

### CROSS-REFERENCE TO RELATED APPLICATION

This application claims priority to Japanese Patent Application No. 2024-002999 filed on Jan. 12, 2024, incorporated herein by reference in its entirety.

### BACKGROUND

### 1. Technical Field

The Disclosure relates to a battery system.

### 2. Description of Related Art

The battery system includes a rechargeable secondary battery. There is technology for cooling a battery by a coolant when an abnormality, such as overheating of the battery, or the like, occurs (Japanese Unexamined Patent Application Publication No. 2004-251220 (JP 2004-251220 A)).

### SUMMARY

However, there are cases in which cooling the battery is difficult. Not cooling the battery may result in damage to the battery system and a vicinity thereof. Accordingly, the present disclosure provides a battery system capable of suppressing damage.

A battery system of the present disclosure includes a battery that is connected to a power system, the battery system including
a detection unit that detects an abnormality in the battery system, and
a battery control unit that, when the detection unit detects an abnormality, causes the battery to execute discharging to the power system.

The battery control unit may cause the discharging to be executed until a state of charge of the battery reaches a predetermined level.

The battery control unit may cause the battery to execute the discharging at a maximum discharge rate.

The detection unit may detect the abnormality based on any one of a current, a voltage, and a temperature, of the battery.

The detection unit may detect the abnormality based on information regarding surroundings of the battery system.

A battery system that is capable of suppressing damage is provided.

### BRIEF DESCRIPTION OF THE DRAWINGS

Features, advantages, and technical and industrial significance of exemplary embodiments of the Disclosure will be described below with reference to the accompanying drawings, in which like signs denote like elements, and wherein:

FIG. 1A is a schematic diagram illustrating a battery system;

FIG. 1B is a schematic diagram illustrating a hardware configuration of a control device; and

FIG. 2 is a flowchart illustrating a process according to the embodiment.

### DETAILED DESCRIPTION OF EMBODIMENTS

### Battery System

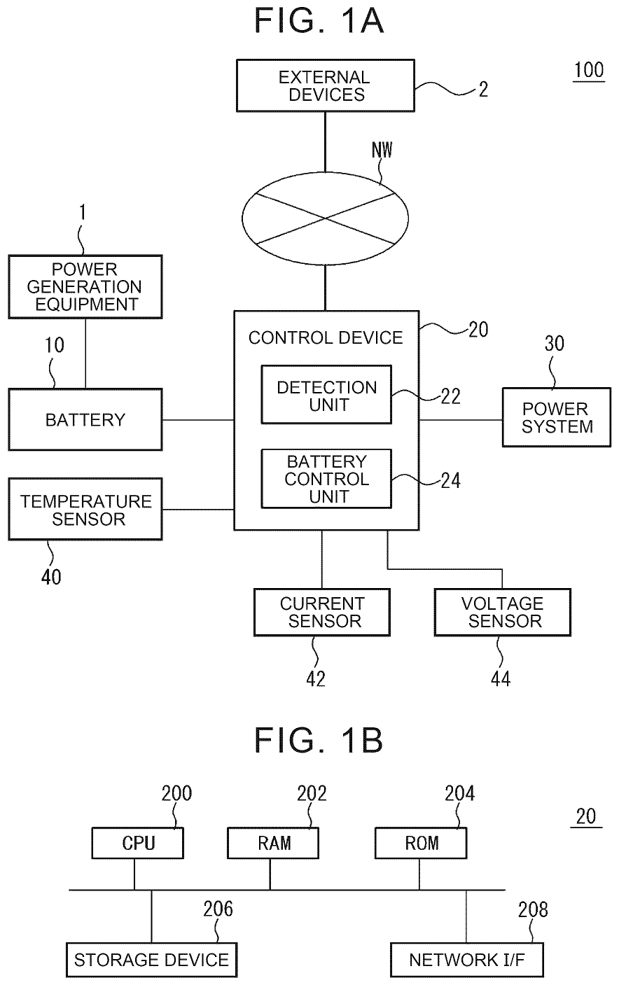

FIG. 1A is a schematic diagram illustrating a battery system 100. The battery system 100 can store the electric power generated by the power generation device 1 and discharge the electric power to the power system 30. The power generation device 1 is, for example, a device using renewable energy, and is a solar power generation device, a wind power generation device, or the like.

The battery system 100 includes a battery 10 and a control device 20. The battery 10 and the control device 20 are electrically connected to each other by a cable or the like. The battery 10 is electrically connected to the power system 30 via the control device 20.

The battery 10 is, for example, a battery pack including a plurality of battery cells. The battery cell includes a secondary battery. The secondary battery is a battery that can be charged and discharged, and is, for example, a lithium ion battery, a lithium ion polymer battery, a nickel metal hydride battery, a nickel cadmium battery, a nickel iron storage battery, a nickel zinc storage battery, a lead storage battery, a silver zinc oxide storage battery, and the like. The battery 10 is charged by electric power generated by the power generation device 1. The battery 10 may discharge power to the power system 30. The State of charge (SOC) of the battery 10 is increased by charge and decreased by discharging. The power system 30 includes an electric wire, a power consumer, and the like.

The battery system 100 includes a temperature sensor 40, a current sensor 42, and a voltage sensor 44. The temperature sensor 40 detects the temperature of the battery 10. The current sensor 42 detects a current flowing through the battery system 100. The voltage sensor 44 detects the voltage of the battery system 100.

The control device 20 of the battery system 100 is connected to the external device 2 via a communication network NW. The external device 2 is a device managed by a public organization and a company, and is, for example, a server or the like. The external device 2 transmits information about surroundings of the battery system 100 to the control device 20. The information is, for example, information on weather, disasters, and the like.

The control device 20 is a battery management system (BMS), includes a computer, and controls the battery system 100. The control device 20 is a control device including an arithmetic device such as a Central Processing Unit (CPU), and storage devices such as a Read Only Memory (ROM) and a Random Access Memory (RAM). The control device 20 performs various kinds of control by executing a program stored in the storage device.

FIG. 1B is a schematic diagram illustrating a hardware configuration of a control device 20. The control device 20 includes a CPU 200, RAM 202, ROM 204, a storage device 206, and a network interface (I/F) 208. CPU 200, RAM 202, ROM 204, the storage device 206, and the network I/F 208 are connected to each other by busses.

The storage device 206 is a non-volatile storage medium such as a hard disk drive (HDD, Hard Disk Drive) and a flash memory. The network I/F 208 is connected to the communication network NW of FIG. 1A.

RAM 202 temporarily stores ROM 204 and programs stored in the storage device 206. When CPU 200 executes the program stored in RAM 202, CPU 200 realizes various functions to be described later, and executes various processes to be described later. The program may correspond to a flowchart described later.

As shown in FIG. 1A, the control device 20 is connected to the battery 10 and the power system 30. The control device 20 is connected to the temperature sensor 40, the current sensor 42, and the voltage sensor 44, and receives signals output from these sensors. The control device 20 acquires the temperature detected by the temperature sensor 40, the current detected by the current sensor 42, and the voltage detected by the voltage sensor 44.

The control device 20 functions as a detection unit 22 and a battery control unit 24. The detection unit 22 detects an abnormality of the battery system 100. The abnormality means a possibility that an abnormality in the state of the battery system 100 or damage to the battery system 100 occurs. Abnormalities include, for example, a current being equal to or greater than a predetermined value, a voltage being equal to or greater than a predetermined value, a temperature of the battery 10 being equal to or greater than a predetermined temperature, and a disaster occurring around the battery system 100. For example, if the temperature of the battery 10 excessively increases, the battery system 100 may be damaged. If the battery system 100 is damaged by a disaster around the battery system 100, the battery 10 may overheat.

The battery control unit 24 controls the battery 10. The battery control unit 24 causes the battery 10 to perform discharging and stops discharging. The battery control unit 24 acquires SOC of the battery 10, the power demand from the power system 30, and the like, and controls the charging and discharging of the battery 10. The battery control unit 24 can control the rate of discharge by the battery control unit 24.

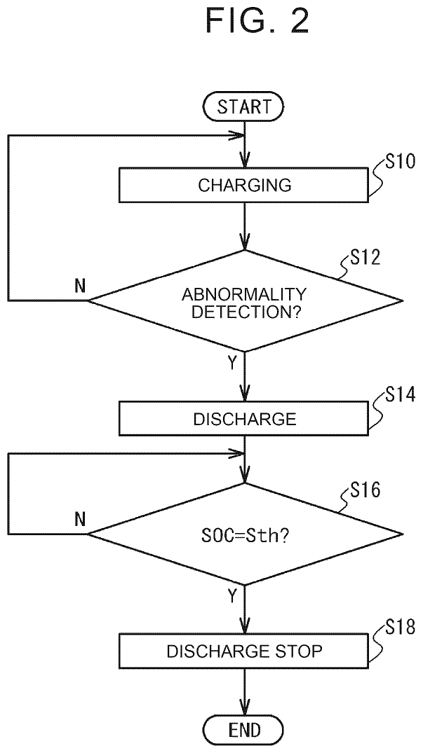

FIG. 2 is a flowchart illustrating a process according to the embodiment. The battery 10 is charged in response to the demand of the power system 30 (S10). The detection unit 22 of the control device 20 monitors the battery system 100 and determines whether or not an abnormality has been detected (S12). If the determination is negative (No), S10 is repeated. If the determination is affirmative (Yes), the battery control unit 24 causes the battery 10 to perform discharging to the power system 30 (S14). The battery control unit 24 sets the discharge rate of the discharge to a maximum rate, for example.

The battery control unit 24 determines whether or not SOC of the battery 10 has reached a predetermined quantity Sth (S16). The predetermined quantity Sth is, for example, 0%. In the case of a negative determination, the discharge is continued. If the determination is affirmative, the battery control unit 24 stops discharging (S18). Thus, the process of FIG. 2 ends.

According to the embodiment, when the detection unit 22 detects an abnormality, the battery control unit 24 causes the battery 10 to perform discharge. The discharging lowers SOC of the battery 10. As SOC decreases, the heat generation of the battery 10 is suppressed, and the current also decreases. Therefore, damage to the battery system 100 can be suppressed.

The battery control unit 24 causes the discharging to be executed until SOC reaches 0%. The discharge depletes the energy of the battery 10. Heat generation is effectively suppressed. The output current and voltage of the battery 10 also decrease. Therefore, damage can be effectively suppressed. SOC after discharging may be 0%, 5% or less, 10% or less, or the like.

The battery control unit 24 causes the battery 10 to perform discharge at the maximum discharge rate. Since SOC of the battery 10 rapidly decreases, damage can be suppressed.

The detection unit 22 may detect an abnormality based on any one of a current, a voltage, and a temperature of the battery 10. For example, in a case where the battery 10 is overheated, in which a large current flows through the battery system 100 and a large voltage is output, the detection unit 22 detects an abnormality. Discharge is performed and SOC is reduced. The current and voltage drop. The temperature of the battery 20 10 is also less likely to increase. Damage can be suppressed. The detection unit 22 may detect an abnormality from an event other than a current or the like.

The detection unit 22 may detect an abnormality based on information around the battery system 100. For example, information indicating that a disaster has occurred in the vicinity of the battery system 100 is transmitted from the external device 2 to the control device 20. The detection unit 22 detects the information of the disaster as an abnormality. The battery control unit 24 discharges the battery 10. The spread of damage can be suppressed.

The battery system 100 is installed at a location away from an urban area or the like, and is installed in, for example, a mountain area or the like. A person may not be resident near the battery system 100. It takes time for a worker, such as a maintenance worker, to arrive at the battery system 100. According to the embodiment, the control device 20 automatically discharges the battery 10. Even if there are no personnel, damage can be suppressed.

While preferred embodiments of the present Disclosure have been described in detail above, the present Disclosure is not limited to such specific embodiments, and various modifications and changes can be made within the scope of the gist of the present Disclosure described in the claims.

What is claimed is:

1. A battery system including a battery that is connected to a power system, the battery system comprising:
a detection unit that detects an abnormality in the battery system; and
a battery control unit that, when the detection unit detects an abnormality, causes the battery to execute discharging to the power system.

2. The battery system according to claim 1, wherein the battery control unit causes the discharging to be executed until a state of charge of the battery reaches a predetermined level.

3. The battery system according to claim 1, wherein the battery control unit causes the battery to execute the discharging at a maximum discharge rate.

4. The battery system according to claim 1, wherein the detection unit detects the abnormality based on any one of a current, a voltage, and a temperature, of the battery.

5. The battery system according to claim 1, wherein the detection unit detects the abnormality based on information regarding surroundings of the battery system.
